(19) United States
(12) Patent Application Publication
(10) Pub. No.: US 2025/0211014 A1
(43) Pub. Date: Jun. 26, 2025

(54) SYSTEMS AND METHODS FOR PRODUCING DITHERED CHARGING SIGNALS

(71) Applicant: Iontra Inc, Centennial, CO (US)

(72) Inventors: Kedar CHITNIS, Bengaluru (IN); Prasad KONNUR, Bengaluru (IN); John Richard HOWLETT, III, Centennial, CO (US); William CHECK, Denver, CO (US); James KRAPOHL, Denver, CO (US)

(21) Appl. No.: 18/987,651

(22) Filed: Dec. 19, 2024

Related U.S. Application Data
(60) Provisional application No. 63/613,684, filed on Dec. 21, 2023.

(51) Int. Cl. H02J 7/00; H03K 7/08

(52) U.S. Cl. CPC H02J 7/00711; H02J 7/0047; H03K 7/08

(57) ABSTRACT

Systems and methods to charge a battery using a switch modulator and a shaping circuit comprising at least one switching element. The shaping circuit may be configured to receive an input charge supply from a power supply and the switch modulator may be operably coupled with the at least one switching element. Further, the switch modulator may actuate the at least one switching element at a selected duty cycle such that the shaping circuit produces a shaped charge signal, the selected duty cycle configured to vary within a switch modulator sample period.

### CROSS-REFERENCE TO RELATED APPLICATIONS

This application is related to and claims priority under 35 U.S.C. § 119(e) from U.S. Patent Application No. 63/613,684 filed Dec. 21, 2023, titled “Systems and Methods for Producing Dithered Charging Signals,” the entire contents of which is incorporated herein by reference.

### TECHNICAL FIELD

Embodiments of the present invention generally relate to systems and methods for charging or discharging a battery using a tunable charging signal.

### BACKGROUND AND INTRODUCTION

Rechargeable batteries are widely used in electrically powered devices such as tools, lawn equipment, mobile computing devices, communication devices, portable electronic devices, household appliances, and electrical vehicles (EVs). Rechargeable batteries are limited by finite battery capacity and must be recharged upon depletion. Because the powered device must often be tethered to an outlet or a charging station during the recharging period, and in some cases may not be used during the recharging period, recharging a battery may be inconvenient to users. In some cases, the recharging period for a battery can last for hours.

High current charging methods have been developed to accelerate charge times. These fast charge systems rely on costly high-power electronics to deliver the required levels of charge current. Because fast charging using these systems can lead to battery degradation and reduced battery performance over time, fast charge systems may include overvoltage circuitry to prevent harmful over-charging of the battery. Including such circuitry and componentry in the charging system further adds to the cost. In some cases, even with protective overvoltage circuitry, high current fast charge solutions may cause damage to the battery. To preserve battery health, high current delivery to the battery is limited when the percentage of battery charge surpasses about 50% during a charging cycle and the remainder of the battery charging up to 100% occurs at a slower rate. Thus, existing fast charge methods and systems are complex, costly, have potential to damage the battery cell, and may not significantly improve wait times associated with charging a battery.

It is with these observations in mind, among others, that aspects of the present disclosure were conceived.

### SUMMARY

One aspect of the present disclosure relates to a charging circuit comprising a controller comprising a switch modulator and a shaping circuit comprising at least one switching element. The shaping circuit may be configured to receive an input charge supply from a power supply, the switch modulator may be operably coupled with the at least one switching element, and the switch modulator may be configured to actuate the at least one switching element at a selected duty cycle such that the shaping circuit produces a shaped charge signal, the selected duty cycle configured to vary within a switch modulator sample period.

Another aspect of the present disclosure relates to a charging circuit comprising a controller comprising a switch modulator and a shaping circuit comprising at least one switching element. The shaping circuit may be configured to receive an input charge supply from a power supply, the switch modulator may be operably coupled with the at least one switching element, and the shaping circuit may be configured to output a first waveform having a first body current and first body time and a second waveform having a second body current and second body time.

Yet another aspect of the present disclosure relates to a method of generating a shaped charge signal. The method may include the features of providing a charging circuit comprising a switch modulator in electrical communication with at least a first switching element within a shaping circuit, providing an input charge supply to the first the switching element, and generating, at the switch modulator, a first instruction signal for controlling the first switching element, wherein the first instruction signal comprises a first sample period, wherein the first sample period is divided into a plurality of PWM cycles, each PWM cycle having a PWM duty cycle. The method may also include the operation of operably controlling the first switching element via the first instruction signal such that, within the first sample period, a first of the plurality of PWM cycles has a first duty cycle and a second of the plurality of PWM cycles has a second duty cycle different from the first duty cycle.

Another aspect of the present disclosure relates to a method of generating a shaped charge signal comprising providing a charging circuit comprising a switch modulator in electrical communication with a first switching element within a shaping circuit, providing an input charge supply to the first the switching element, and generating, at the switch modulator, a first instruction signal for controlling the first switching element. The method may also include the operations of operably controlling the first switching element to generate a first shaped waveform having a first body current and a first body time and operably controlling the first switching element to generate a second shaped waveform having a second body current and a second body time.

Yet another aspect of the present disclosure relates to a method of generating a shaped charge signal comprising providing a charging circuit comprising a switch modulator, the switch modulator in electrical communication with a first switching element of a first shaping circuit and in electrical communication with a second switching element of a second shaping circuit, providing an input charge supply to the first the switching element and the second switching element, and generating, at the switch modulator, a first instruction signal for controlling the first switching element and a second instruction signal for controlling the second switching element. The method may also include the operations of operably controlling the first switching element to generate a first shaped waveform having a first body current and a first body time and operably controlling the second switching element to generate a second shaped waveform having a second body current and a second body time.

### BRIEF DESCRIPTION OF THE DRAWINGS

The various objects, features, and advantages of the present disclosure set forth herein will be apparent from the following description of embodiments of those inventive concepts, as illustrated in the accompanying drawings. Drawings presented herein are not necessarily to scale and may be representative of various features of an embodiment, with emphasis being placed on illustrating the principles and other aspects of the inventive concepts. Also, in the drawings the like reference characters may refer to the same parts or similar throughout the different views. It is intended that the embodiments and figures disclosed herein are considered illustrative rather than limiting.

FIG. 1 is a block diagram of a charging circuit in accordance with embodiments herein.

FIG. 2 is a block diagram of a portion of a charging circuit sending and receiving instruction signals in accordance with embodiments herein.

FIG. 3 is a block diagram of a portion of a charging circuit in accordance with embodiments herein.

FIG. 4A is an example target waveform in accordance with embodiments herein.

FIG. 4B is an example lookup table relating current value and duty cycle in accordance with embodiments herein.

FIG. 4C is an example actual waveform in accordance with embodiments herein.

FIGS. 5A and 5B are a block diagram of a portion of a charging circuit and a visualization of an instruction signal, respectively, in accordance with embodiments herein.

FIG. 6 is a visualization of an instruction signal in accordance with embodiments herein.

FIGS. 7A and 7B are a block diagram of a portion of a charging circuit and a visualization of an instruction signal, respectively, in accordance with embodiments herein.

FIGS. 8A and 8B are a block diagram of a portion of a charging circuit and a visualization of an instruction signal, respectively, in accordance with embodiments herein.

FIG. 9A is an example target waveform in accordance with embodiments herein.

FIGS. 9B and 9C are visualizations of instruction signals in accordance with embodiments herein.

FIGS. 10, 11, and 12 are example shaped charge signals in accordance with embodiments herein.

FIG. 13 is a block diagram of a portion of a multiphase charging circuit in accordance with embodiments herein.

FIG. 14A is an example of a shaped charge signal in accordance with embodiments herein.

FIG. 14B is an example of a plurality of shaped charge signals produced by a multiphase charging circuit in accordance with embodiments herein.

FIG. 15A is an example of a shaped charge signal in accordance with embodiments herein.

FIG. 15B is an example of a plurality of shaped charge signals produced by a multiphase charging circuit in accordance with embodiments herein.

FIG. 16 a diagram illustrating an example of a computing system which may be used in implementing embodiments of the present disclosure.

### DETAILED DESCRIPTION

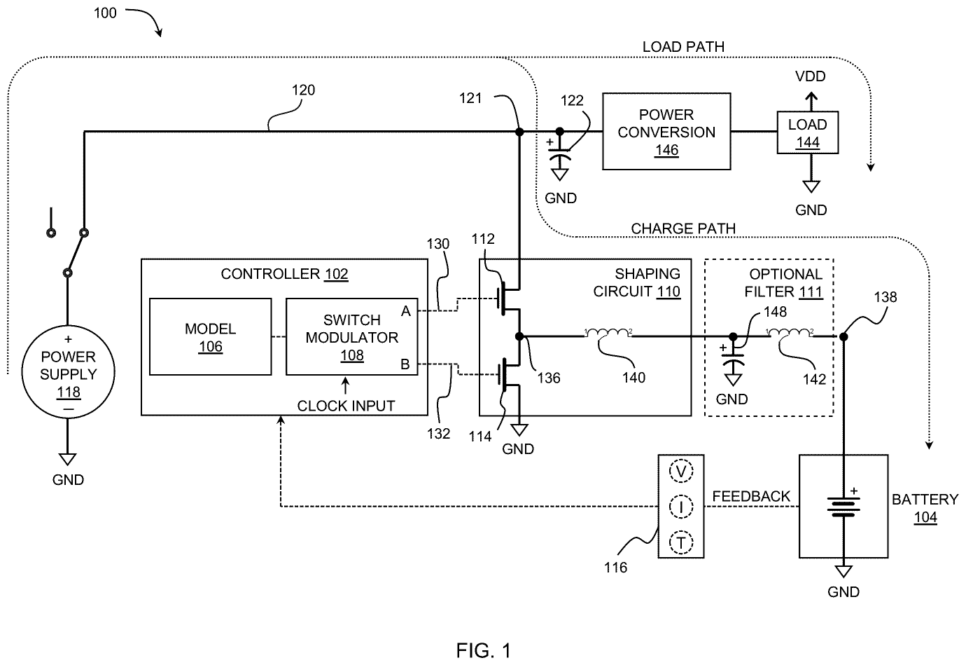

FIG. 1 shows a block diagram of a charging system 100. The system 100 includes a charge path for charging a battery 104 and a load path for powering a load 144, the two paths depicted in dotted lines. The charge and load paths are the same from power source 118 and along bus 120 up to node 121. Power source 118 may generate an input charge supply in the form of an AC or DC input charge supply. In embodiments where power source 118 generates an AC signal, an AC/DC converter may be included ahead of node 121 to convert the input charge supply to a DC signal. Along the load path after node 121, a capacitor 122 and a power conversion module 146 are included ahead of load 144. The capacitor 122 and load 144 are electrically grounded.

Along the charge path after node 121, the system 100 includes a controller 102 in communication with a shaping circuit 110. The controller 102 may include a model 106 in communication with a switch modulator 108 such that the switch modulator 108 may access information from the model 106. In some embodiments, the model stores information about the battery 104 such as battery type, battery conditions (e.g., state of charge (SOC), state of health (SOH), battery temperature, voltage, current, impedance, safety thresholds, etc.), environmental conditions (e.g., environmental temperature, moisture levels, etc.), or other factors that may affect charging of a battery. The model 106 may receive feedback information about battery size, type, and/or conditions from a battery monitoring module 116. The feedback information may include sensor measurements (e.g., temperature, voltage, current, etc.) and/or calculated or derived information (e.g., SOC, SOH, impedance, etc.). This feedback information may be used to update the model 106, predict battery behavior, select a target shaped charging signal profile, and/or may be used to generate instruction signals via the switch modulator 108 for one or more switching elements within the shaping circuit 110. The switch modulator 108 may include, or may itself be, a pulse width modulator (PWM) and may further be configured to receive a clock input from a clock module (not shown).

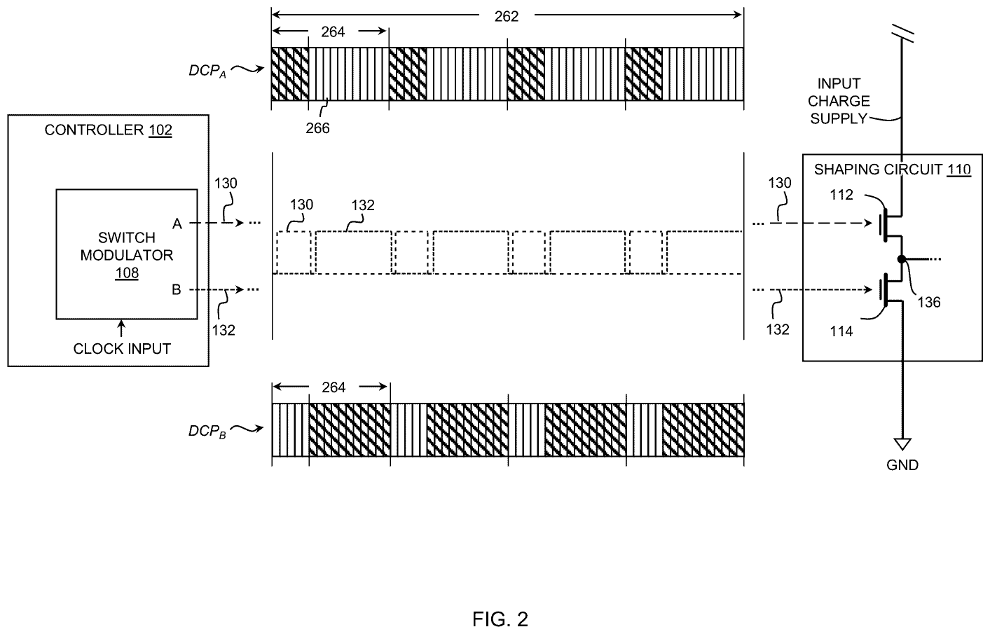

In the system 100, shaping circuit 110 includes a first switching element 112 and a second switching element 114. The switching elements may be electrically controlled switching elements such as transistors, field effect transistors (FET), or more particularly metal-oxide-semiconductor field-effect transistors (MOSFET), Gallium Nitride (GaN) FETs, Silicon Carbide based FETs, or any other type of wired or wireless controllable switching element suitable for operating at the power levels of any given use case or implementation. The first and second switching elements 112, 114 each include a source, a gate, and a drain. The source of the first switching element 112 is electrically coupled with the bus 120 (e.g., at node 121) and is configured to receive an input charge supply from power supply 118. The gate of the first switching element 112 is configured to receive a first instruction signal 130 from switch modulator 108 within controller 102. The drain of first switching element 112 is electrically coupled with a source of the second switching element 114 (e.g., at a node 136) such that the first and second switching elements are arranged in series. The gate of the second switching element 114 is configured to receive a second instruction signal 132 from the switch modulator 108, and a drain of the second switching element is connected to ground. Detailed discussion about the operation of switch modulator 108 and instruction signals 130, 132 is included below with respect to FIGS. 2-4C.

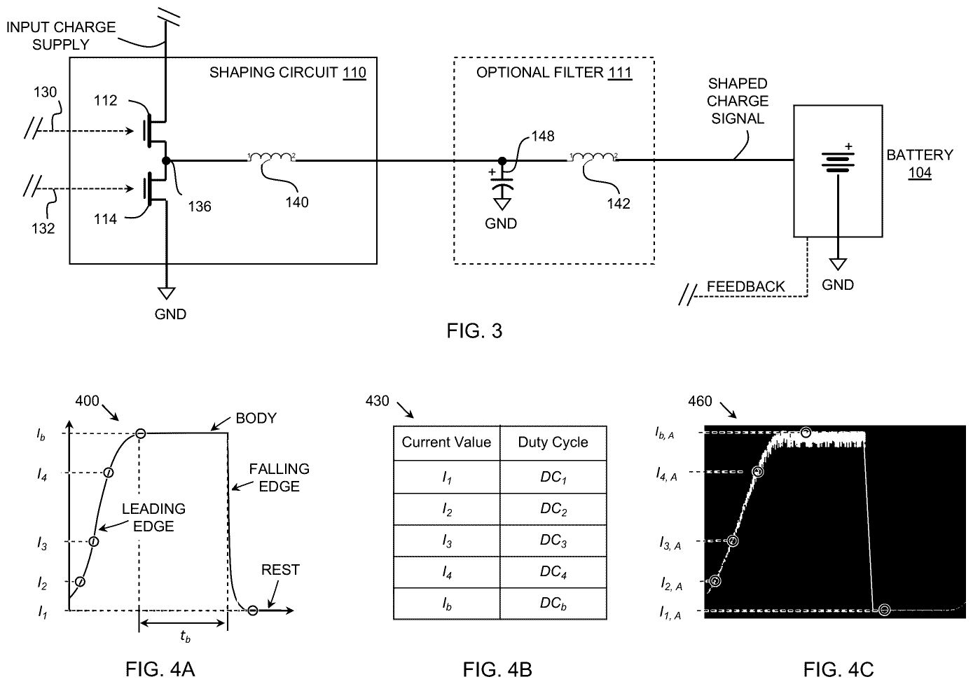

Shaping circuit 110 further includes at least one component downstream of the switching elements 112, 114. The additional component may be a first inductor 140. An optional filter 111 may be included following the shaping circuit 110. The filter 111 may include a capacitor 148 and a second inductor 142. The first inductor 140 in addition to components within the optional filter may be configured to shape the cyclical charge supply generated at node 136 by the controlled switching of switching elements 112, 114. The inductors 140, 142 and capacitor 148 are configured to modify input charge supply received from node 136 such that a shaped charge signal is generated for delivery to the battery 104 for charging. Detailed discussion about the operation of shaping circuit 110 is included below with respect to FIGS. 3-4C.

In one example, the various embodiments discussed herein charge a battery cell by generating an arbitrary charge signal that is shaped using a pair of transistors controlled through a signal shaping generator. In particular, the pair of transistors may be controlled with a pulse-width modulation (PWM) signal with a duty cycle. In general, the duty cycle of the PWM controlling the operation of the transistors correlates to a charge current applied to the battery, such that a higher duty cycle of the PWM control signal results in a higher current applied to charge the battery. The signal shaping generator may receive a target shaped charge signal and use the duty cycle of the PWM control signal to shape a charge signal for the battery that corresponds to the target shape. The shaping process of the charge signal be executed iteratively to gradually shape subsequent portions of the charge signal closer and closer to the target charge signal shape. This iterative process may include controlling the transistors at a first duty cycle of the PWM control signal, receiving a measurement of some aspect of the battery under charge, determining an error between the measurement and a target performance, and adjusting the duty cycle of the PWM control signal based on the determined error. The charge signal for the battery is therefore gradually shaped to match or approximate the shape of the target charge signal through multiple adjustments to the duty cycle of the PWM signal. This shaped charge signal may provide a more efficient charge signal for the battery that mitigates damaging effects of more traditional charge signals.

The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells, such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries of various possible chemistries, to name a few. The various implementations discussed herein may also apply to different structural battery arrangements such as button or “coin” type batteries, cylindrical battery cells, pouch battery cells, and prismatic battery cells.

Referring now to FIG. 2, a detailed view of controller 102 providing instruction signals 130, 132 to switching elements 112, 114 is illustrated. The switch modulator 108 may include two channels (e.g., A and B) for generating two instruction signals 130, 132 for the first and second switching elements, respectively. The instruction signals 130, 132 may be substantially opposite such that when the first switching element 112 is on (e.g., node 136 is electrically connected to bus 120 and receives input charge supply), the second switching element 114 is off to prevent input charge supply from shooting through to ground. Similarly, when first switching element 112 is off (e.g., node 136 is electrically disconnected from bus 120), the second switching element 114 is turned on to connect first inductor 140 to ground. In some embodiments, a small delay (e.g., dead time) may be built into the system before each turn on event for the first and second switching elements. This dead time prevents both switching elements from being on at the same time and sending input charge supply directly to ground.

To generate the instruction signals 130, 132, switch modulator 108 operates each channel (e.g., channel A and channel B) according to a duty cycle profile (e.g., DCP_{A} and DCP_{B}). The sample period 262 may be subdivided into a plurality of PWM cycles 264, each of which may be further subdivided into a plurality of step increments 266. PWM cycles 264 may represent the minimum amount of time over which a switching element duty cycle is controlled or calculated. Step increments 266 represent the minimum amount of time for which the switch modulator 108 can control the instruction signal to be on or off. In example duty cycle profile A (DCP_{A}), the first five increments are on, as represented by the hatched rectangles, and the remaining eleven increments are off, as represented by the white rectangles. The duty cycle for a PWM cycle 264 is calculated by comparing the number of step increments that are turned on within a PWM cycle to the total number of step increments within the PWM cycle. For DCP_{A}, the duty cycle is 5/16, or 31.25%. Correspondingly, in duty cycle profile B (DCP_{B}), the first five increments are off, as represented by the white rectangles, and the remaining eleven increments are on, as represented by the hatched rectangles. The duty cycle for the first PWM cycle of DCP_{B} is 11/16, or 68.75%. Small amounts of dead time may be included within the instruction signals as discussed above, but these small periods are omitted from the duty cycle calculations for simplicity.

In the system illustrated in FIG. 2, each of a plurality of PWM cycles 264 within the sample period 262 has the same duty cycle. Operating the system to have a consistent PWM cycle repeated over the entire sample period 262 is a referred to herein as a non-dithered method of operation. In the non-dithered method, the duty cycle averaged over the sample period 262 is equal to the duty cycle calculated at each PWM cycle 264 contained therein. In this example, duty cycle calculated over the sample period 262 is 20/64 (31.25%) for DCP_{A} and 44/64 (68.75%) for DCP_{B}.

The precision (e.g., given in time units such as microseconds or nanoseconds) of a non-dithered system is correlated to the size (e.g., given in time units such as microseconds or nanoseconds) of step increments 266 within the PWM cycle 264. The size of step increments may be determined at least in part by the speed (e.g., given in Hz) of the clock that regulates the switch modulator 108. Precision of the non-dithered system may be calculated according to Equation 1 below:

$$Precision = 1 / ( Clock Speed ) . \qquad Eq . 1$$

For example, if the clock speed is 1 GHz, the precision (e.g., the duration of each step increment 266) is given by Equation 2 below:

$$Precision = \frac{1}{1 \times 1 {0}^{9} Hz} = 1 \times 1 {0}^{- 9} seconds = 1 nanosecond . \qquad Eq . 2$$

The precision of a switch modulator and, correspondingly, the precision of instruction signals sent to switching elements by the switch modulator, affects a charging system's ability to produce a target charging signal. In some embodiments, the target charging signal includes shaped charging waveforms which may be difficult or impossible to produce with accuracy if the system lacks sufficient precision. The inverse relationship between precision and clock speed described by Equations 1 and 2 indicates that finer precision in a system may be achieved by using a faster clock. Higher precision in a system may be desirable, especially when generating a specific shaped charging waveform as described now with respect to FIGS. 3 and 4A-4C.

Referring to FIG. 3, a detailed view of shaping circuit 100, optional filter 111, and battery 104 of system 100 is illustrated. Instruction signals 130, 132 are communicated to the gates of first and second switching elements 112, 114, respectively, as discussed above with respect to FIG. 2. The switching elements 112, 114 as controlled by the instruction signals 130, 132 modify the shape and/or magnitude of the input charge supply from bus 120 to generate a modified input charge supply that is delivered to first inductor 140 via node 136. The first inductor 140, along with components included within the filter 111, further adjust the shape and/or magnitude of the modified input charge supply to output a shaped charge signal for the battery 104. For example, the arrangement of inductors and the capacitor(s) within the shaping circuit 110 and filter 111 may function to smooth out high frequency components of the modified input charge supply and/or may act to gradually aggregate or dissipate current such that a ramped, curved, cyclical, sinusoidal, and/or otherwise shaped portion of a charge signal is generated.

Referring to FIGS. 4A, 4B, and 4C together, examples of a target shaped charging waveform 400, a current value to duty cycle lookup table (LUT) 430, and an actual shaped charging waveform 460 are shown, respectively. The target shaped charging waveform 400 may be an ideal shaped charging waveform for charging the battery 104. Charging speed, battery health, and/or other metrics may be prioritized when selecting or generating the target shaped charging waveform 400, and the waveform 400 may be selected or generated by the model 106 based on information or predictions about the battery. The waveform 400 includes a leading edge, a body, a falling edge, and a rest period. The leading edge may be ramped, curved, linear, or sinusoidal in shape or may be a piecewise combination of different shapes and/or linear slopes. The characteristics of the ramp, curve, or sinusoidal frequency of the leading edge may be selected (e.g., by the model 106) based on one or more measured, calculated, or predicted characteristics of the battery and/or the surrounding environment (e.g., temperature, voltage, impedance, SOC, SOH, type of battery, size of battery, age of battery, charge cycle count, etc.).

The leading edge of waveform 400 ramps up to the body portion. The body portion may be held at a substantially constant body current value (I_{b}) over a body time (t_{b}) and, in some embodiments, the body current may be the maximum current value for the waveform 400. Following the body portion is a falling edge where current decreases from the target body current (I_{b}) to a rest current, which is less than the target body current and may be near or equal to zero. The falling edge may be ramped, curved, sinusoidal, curved, and/or a piecewise combination of different shapes and/or linear slopes. In some embodiments, an optional cold weather mitigation signal may be included during or after the rest portion and before the leading edge of the next instance of the repeating waveform 400. The cold weather mitigation signal (not shown) may be a repeated sinusoidal signal or an otherwise cyclical or oscillating signal and, in some embodiments, the maximum current achieved by the cold weather mitigation signal is less than the target body current.

Each point along the target waveform 400 has a target current value I. Five arbitrary points along waveform 400 are selected as examples and their associated currents are labeled I₁, I₂, I₃, I₄, and I_{b}. Current I₁ is a target resting current associated with a rest period; currents I₂, I₃, and I₄ are target currents associated with three different points along the shaped leading edge. Current I_{b} is a target body current associated with a body portion of waveform 400, as discussed above. Each target current on the target waveform 400 is associated with a duty cycle of a switching element (e.g., first switching element 112) that electrically connects the battery 104 to a power supply 118.

FIG. 4B shows an example lookup table 430 that associates a switching element duty cycle (e.g., DC₁, DC₂, DC₃, DC₄, DC_{b}) with a current value (e.g., I₁, I₂, I₃, I₄, and I_{b}) on the target waveform 400. The duty cycle in this example may be a first duty cycle associated with the first switching element 112 that electrically couples the first inductor 140 with bus 120 such that the first inductor 140 receives an input charge supply. Duty cycle of the second switching element 114 may be determined as a function of the first switching element duty cycle as discussed above. Relatively speaking, lower currents are associated with lower duty cycles of the first switching element and higher currents are associated with higher duty cycles of the first switching element, though the relationship between duty cycle and output current may not be linear. The controller 102 (e.g., the model 106 included within the controller 102) may select the target waveform 400 based on information about the battery and may generate a series of duty cycle instructions (e.g., using a lookup table similar to table 430) that change over time in order to cause shaping circuit 110 to generate a shaped charge signal having actual waveforms that conform to the target shaped charging waveform 400. While a lookup table is shown, equations or other models or predictive tools may be used to relate a desired current value to a switching element duty cycle.

FIG. 4C illustrates an example of an actual shaped charge waveform 460 generated as a result of operating the first and second switching elements 112, 114 according to the duty cycle instructions (e.g., via switch modulator 108 and instruction signals 130, 132). The leading edge, body portion, falling edge, and rest period of actual waveform 460 are substantially the same shapes and magnitudes as those described by target waveform 400. A high frequency oscillation may be present in the actual waveform 460 and may be an artifact resulting from the rapid opening and closing of switching elements 112, 114. Additional filtering elements (e.g., within optional filter 111 of FIG. 3) may be included within the circuit 100 to reduce noise and reduce deviations of the actual waveform 460 from the target waveform 400. A series of waveforms 460 may be generated to form a shaped charge signal that is delivered to the battery 104 for charging.

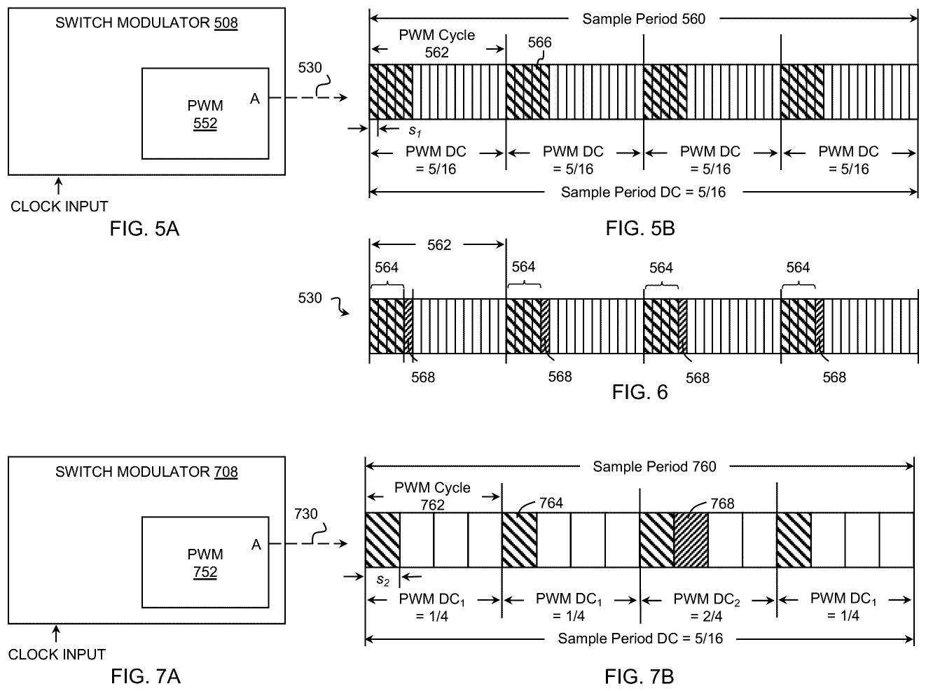

Referring to FIGS. 4A-5B and Equation 1 together, the relationship between precision, clock speed, and actual waveform fidelity to the target waveform is described. Target waveform 400 may be selected for a specific set of battery characteristics in order to optimize charging speed, battery life cycles, temperature levels, and/or other prioritized metrics. Reproducing a high-resolution target waveform 400 in an actual waveform 460 may require fine control over current values, and correspondingly, fine control over duty cycle increments. Equation 1 describes that the increment of duty cycle adjustment (e.g., precision or step increment s₁) is a function of clock speed.

An example is provided in FIGS. 5A-5B to further demonstrate this relationship. FIG. 5A shows a switch modulator 508 which may include, or may itself be, a pulse width modulator (PWM) 552. For simplicity, only a first instruction signal 530 for the first switching element is shown and described, though a second instruction signal for the second switching element is generated as described with respect to FIG. 2. The switch modulator 508 receives a clock input from a clock module (not shown). For each clock input, the switch modulator 508 (e.g., via a PWM 552) may instruct an associated switching element to turn on or off. A visualization of the instruction signal 530 is provided in FIG. 5B where a sample period 560 includes four PWM cycles 562. Each PWM cycle 562 includes 16 equal step increments of duration s₁, though more or fewer PWM cycles and step increments may be included within a sample period. The duration s₁ is a function of the frequency at which clock inputs are received, where a faster clock module decreases duration s₁ and a slower clock module increases the duration s₁. To reduce processing demand, each PWM cycle 562 within a sample period 560 is identical. In this example, the PWM duty cycle (PWM DC) of each PWM cycle 562 is equal to a target duty cycle of 5/16. When averaged over the sample period 560, the sample period duty cycle (Sample Period DC) is equal to each PWM DC at 5/16.

Duty cycle in the system of FIGS. 5A and 5B can be adjusted in 1/16 (e.g., 6.25%) increments. The precision of the system may also be described in absolute terms using duration s₁. For example, as discussed with respect to Equation 2, if clock speed is 1 GHz, step increment duration s₁ equals 1 nanosecond. The 5/16 duty cycle of instruction signal 530 includes an “on” portion (e.g., as indicated by hatched rectangles) lasting approximately 5 nanoseconds and an “off” portion (e.g., as indicated by white rectangles) lasting approximately 11 nanoseconds for each PWM cycle 562. The total “on” time for the sample period 560 is 20 nanoseconds. As described in table 430, the duty cycle for a given clock speed and the amount of “on” time are associated with a current level output from the shaping circuit 110.

In some embodiments, a high frequency clock may be impractical to use due to excessive cost or system complexity. An alternative method for operating a switch modulator-based system is described that enables a lower frequency clock to achieve duty cycle precision similar to or the same as a high frequency clock when calculated over a sample period. This method may be referred to herein as “PWM dithering” and the method is described with respect to FIGS. 6 and 7A-7B. While examples are provided in the context of generating a shaped charge signal, concepts described herein may be leveraged to reduce clock demands and/or improve signal precision in other fields and applications as well.

FIG. 6 shows another visualization of the instruction signal 530 where each PWM DC and the sample period duty cycle are equal to a target sample period duty cycle of 5/16 as described in the example of FIG. 5B. However, in FIG. 6, the five “on” increments within each PWM cycle 562 are broken down into a first group 564 (i.e., the course hatched rectangles) and a second group 568 (i.e., the fine hatched rectangles). The alternative method for operating the switch modulator is based on producing an “on” duration substantially equivalent to the duration of the first group 564 at each PWM cycle. Another “on” duration is included within the sample period that is substantially equivalent to an aggregated duration of the second group 268 (i.e., the sum of each fine hatched rectangle contained within the sample period). This aggregated “on” duration is included in one or more, but less than all, of the PWM cycles. Thus, according to this alternative method of operation, a single sample period includes PWM cycles with different PWM DC values.

The sample period resulting from the rearrangement of “on” time is illustrated in detail in FIGS. 7A-7B. A switch modulator 708 includes, or is itself, a PWM 752 and receives a clock input. The PWM 752 creates an instruction signal 730 for a switching element (e.g., first switching element 112). For simplicity, only a first instruction signal 730 for the first switching element is shown and described, though a second instruction signal for the second switching element is generated as described with respect to FIG. 2. The instruction signal 730 includes four PWM cycles 762 within a sample period 760. The PWM cycle 762 has the same time duration as PWM cycle 562 and the sample period 760 has the same time duration as sample period 560. The step increment duration s₂ is 4× longer than the step increment duration s₁, which corresponds to a 4× decrease in clock speed for the system of FIG. 7A compared with the system of FIG. 5A. PWM cycles 762 within sample period 760 have four step increments.

Each of the PWM cycles of sample period 760 has at least a base level of “on” increments. This base level of “on” duration is generally equivalent to the duration of the first group 564 (FIG. 6). PWM cycles with only the base number of “on” steps have a first PWM duty cycle, PWM DC₁. In this example, PWM DC₁ is equal to ¼ (25%). The third PWM cycle within sample period 760 also includes a second “on” step 768 represented by the fine hatched rectangle. The duration of the second “on” step 768 is equivalent to, or within a tolerance of, the aggregated duration of the second group 268 (FIG. 6). PWM cycles with the base number of “on” steps plus the aggregated “on” step(s) have a second PWM duty cycle, PWM DC₂. In this example, PWM DC₂ is equal to 2/4 (50%).

While the third PWM cycle was arbitrarily selected to include the aggregated “on” step, any of the PWM cycles could have been selected. Additionally, while the aggregated “on” step 768 is located adjacent to the base “on” step within the third PWM cycle to create a single continuous “on” duration, this is not a requirement and any step increment within the PWM cycle may be turned on without departing from the scope of the presently described method. Similarly, while each first step increment within the PWM cycles is illustrated as being turned on to represent the base level of “on” increments, any step increment within the PWM cycle may be selected for this purpose.

Still referring to the example of FIG. 7B, none of the individual PWM cycles 762 within the sample period 760 have the exact target duty cycle of 5/16; however, when an average duty cycle for the sample period 760 is calculated, 5/16 step increments are “on” increments and the amount of “on” time is 20 nanoseconds. Thus, using a clock module with 4× reduction in speed compared to that of FIG. 5A, the system of FIG. 7A produces the same average duty cycle and total “on” time over a sample period. This advantage is enabled by the ability to include PWM cycles with different PWM duty cycles within a single sample period.

While a 4× reduction in clock speed is described in this example and a single aggregated step increment is included within the sample period 760, other variations are contemplated. For example, in some applications it may be advantageous to reduce the difference between PWM DC₁ and PWM DC₂. A system with 2× reduction in clock speed and 2× reduction in number of increments within a PWM cycle compared with the system of FIGS. 5A-5B may be used. In such an embodiment, the aggregated step increment may be split into two instances that are distributed to different PWM cycles such that two PWM cycles have a first duty cycle and two PWM cycles have a second duty cycle while the sample period duty cycle remains equal to the target duty cycle. In some embodiments, it may be possible for one or more of the PWM duty cycles to match a target duty cycle for the sample period. Additionally, in some embodiments, more than two different PWM duty cycles may be included within a sample period.

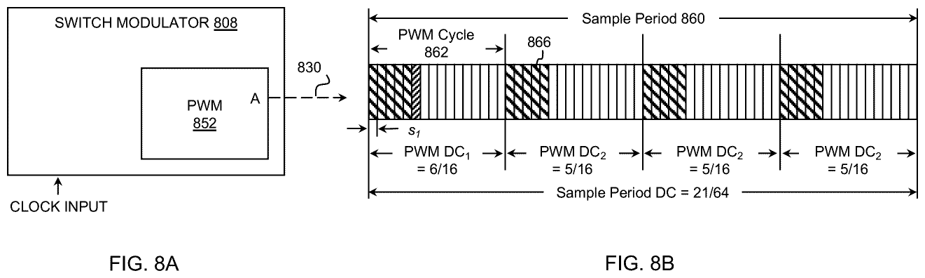

The PWM dithering method described above may also be used to increase resolution of a system without increasing the clock speed. In some embodiments, a target waveform calls for producing a current that is associated with a duty cycle that falls in between a system's step increment resolution. An example is described with respect to FIGS. 8A-8B where a target waveform calls for a current that is associated with a duty cycle of 21/64 (e.g., an average of 5.25 nanoseconds per PWM cycle in the case where clock speed is 1 GHz); however, the precision of each PWM cycle 862 within the sample period 860 of instruction signal 830 is 1/16 (e.g., 1 nanosecond). According to the method of operation described where each PWM cycle 862 within a sample period 860 is the same, the switch modulator 808 can generate either a 5/16 duty cycle or 6/16 duty cycle over the sample period, but cannot further subdivide to achieve the required 21/64 duty cycle. Using the dithering method of operating the switch modulator 808 and/or PWM 852, one of the PWM cycles (e.g., the first PWM cycle 862) may be operated such that one additional step increment is turned on and PWM DC₁ is 6/16. This additional step may be referred to herein as a “dithered” step and the PWM cycle in which the dithered step is located may be referred to as a dithered PWM cycle. The remaining three PWM cycles within the sample period are operated such that PWM DC₂ is 5/16 and the Sample Period DC is equal to the target duty cycle of 21/64. This approach reduces demands on the clock module and provides an alternative to purchasing expensive upgraded clocks, accepting high deviations between target waveforms and actual waveforms, and/or compromising the target waveform by simplifying the optimized signals. Meeting demands of target waveforms using the proposed method may advantageously provide for faster battery charging and/or reduced damage to a battery.

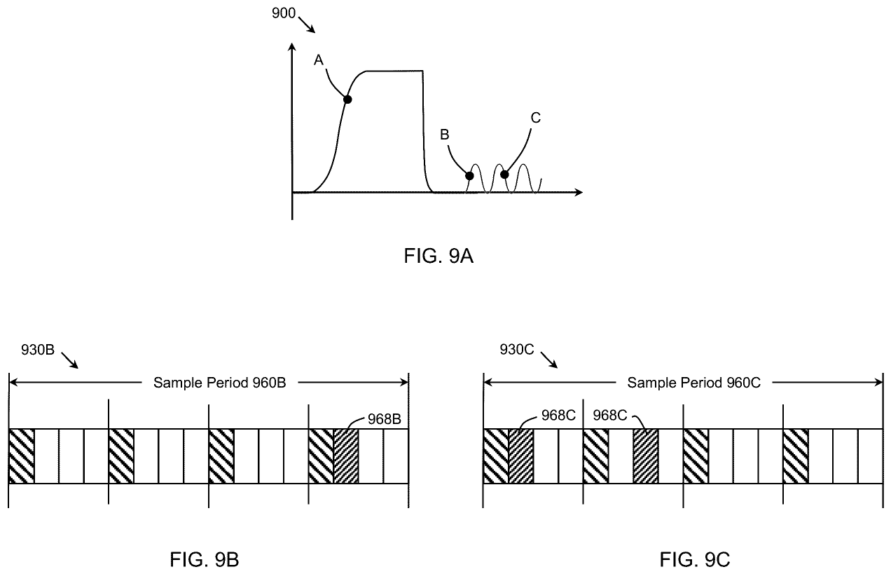

Referring briefly to FIGS. 9A-9C, a target waveform 900 includes a leading edge, body portion, falling edge, rest period, and a cold weather mitigation portion (e.g., the repeating sinusoidal shapes after the falling edge). Points A, B, and C of the waveform 900 are labeled. Points A and B are located on portions of the charging waveform where current is increasing, and Point C is located on a portion of the charging waveform where current is decreasing. FIGS. 9B and 9C show example instruction signals 930B and 930C, respectively. The instruction signals 930B, 930C each include four PWM cycles therein, with each PWM cycle divided into four step increments.

In some PWM dithering embodiments, placement of one or more of the additional “on” step increments (e.g., as described with respect to FIGS. 7B and 8B above) may be determined based on which part of the waveform 900 is being generated during the particular sample period. For sample periods associated with points on the waveform 900 that have an increasing current (i.e., Points A and B), an instruction signal such as signal 930B may be used where the dithered “on” step 968B is instantiated later in the sample period. For example, the dithered step 968B may occur in the second half of the sample period or within the last PWM cycle. While the step 968B is shown as being adjacent to a base “on” step (e.g., represented by course hatched rectangles), this is not a requirement. In some embodiments, the dithered step 968B may be placed within the second half of the last PWM cycle or within the last step increment of the PWM cycle. By placing the dithered step later in the sample period and/or PWM cycle, the current change over the sample period may increase to facilitate or align with a ramping up of the current according to the overall trajectory of waveform 900 around the Points A and B.

Similarly, for Point C where current of the waveform 900 is decreasing, the dithered step(s) 968C in instruction signal 930C may be placed nearer to the beginning of the sample period 960C. In some embodiments, one or more dithered steps 968C may occur within the first half of the sample period 960C. Two dithered steps 968C are illustrated in this example, a first being located adjacent to a base “on” step (e.g., represented by course hatched rectangles) and a second being located following an “off” step increment (e.g., as represented by white rectangles). By placing dithered step(s) earlier in the sample period and/or PWM cycle, the current change over the sample period 960C may decrease to facilitate or align with a ramping down of the current according to the overall trajectory of waveform 900 around the Point C.

While not specifically illustrated, a sample period associated with generating current for a portion of the body period of waveform 900 may benefit from having dithered “on” steps as evenly spaced across the sample period as possible. For example, in embodiments having more than one dithered step, it may be advantageous to place half of the dithered steps in the first half of the sample period and the remaining half of the dithered steps in the second half of the sample period. Additionally, if dithering occurs over several adjacent sample periods within an instruction signal, evenly spacing the dithering steps such that they occur on substantially regular intervals may reduce the amount of noise introduced into the signal.

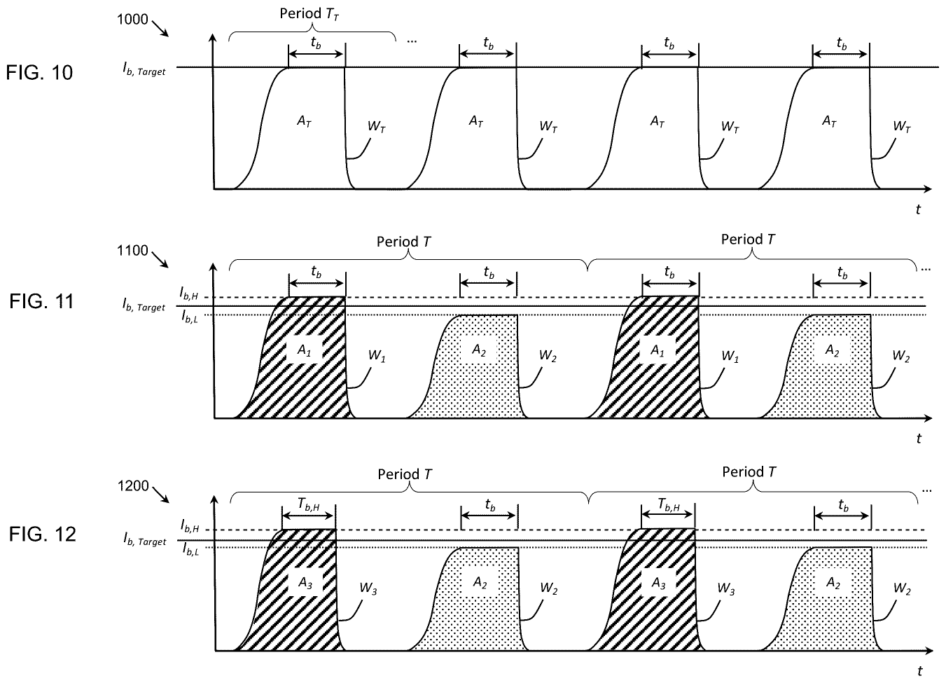

Referring now to FIGS. 10-12, dithering at a waveform level is described. FIG. 10 illustrates a plurality of repeating target waveforms that form a target shaped charge signal 1000 (e.g., as output by the shaping circuit 110 for delivery to a battery 104). Each target waveform W_{T} has a shaped leading edge, a body portion, a falling edge, and a rest portion that occur within the repeating target period, T_{T}. The body portion of the waveform W_{T} includes a steady body current having a magnitude, I_{b,Target} that is held over a body period time, t_{b}. A target area A_{T} under the waveform curve represents the amount of current delivered to the battery by the waveform over the period T_{T}. In some embodiments, the target body current magnitude I_{b,Target} and the target area A_{T} are selected (e.g., by the controller 102 and/or model 106) to optimize battery charging speed without degrading the life of the battery. As discussed in detail above, PWM dithering may be used to generate an actual waveform, including a body portion thereof, with shape and magnitude closely matching the target waveform. In some embodiments, waveform-level dithering may be used instead of, or in addition to, PWM-level dithering to account for limitations in the charging circuit 100.

FIG. 11 shows an example of a shaped charge signal 1100 that includes waveform-level dithering. In some embodiments, a charging circuit may lack sufficient resolution to achieve the exact target body current magnitude I_{b,Target} at each waveform. Rather, the charging circuit may be able to hold a steady body current at a lower current magnitude I_{B,L} that is less than I_{b,Target} or at a higher current magnitude I_{B,H} that is greater than I_{b,Target}. In signal 1100, waveforms having body currents at I_{B,L} and I_{B,H} are generated at a ratio such that an average of the body currents is equal to, or within tolerance of, a target body current I_{b,Target}. The average body current may be calculated by multiplying the body current for each waveform in the period T by the body time and dividing by the body time within the period T. The number of waveforms used to generate an average body current within tolerance of the target body current I_{b,Target} may determine how many waveforms are included in the repeating period T.

Within signal 1100, a first waveform W₁ having a high body current I_{b,H} and associated area A₁, and a second waveform W₂ having a low body current I_{b,L} and associated area A₂ are generated. In this case, the target body current I_{b,Target} is centered between the low body current I_{b,L} and high body current I_{b,H} such that an average body current calculated over one waveform W₁ and one waveform W₂ equals the target body current I_{b,Target}. This calculation is described by Equation 3 below.

$$Avg . Body Current = \frac{( {I}_{B , L} \times {t}_{b} ) + ( {I}_{B , H} \times {t}_{b} )}{( {t}_{b} + {t}_{b} )} = {I}_{b , T a r g e t} . \qquad Eq . 3$$

Thus, the repeating period T achieves the average body current using two waveforms. While achieving an average target body current over a period is described above, it is possible to take a similar approach to adjusting the shaped charge signal using modifications to the body current and/or body current time to obtain an average target area A_{T} over a period T.

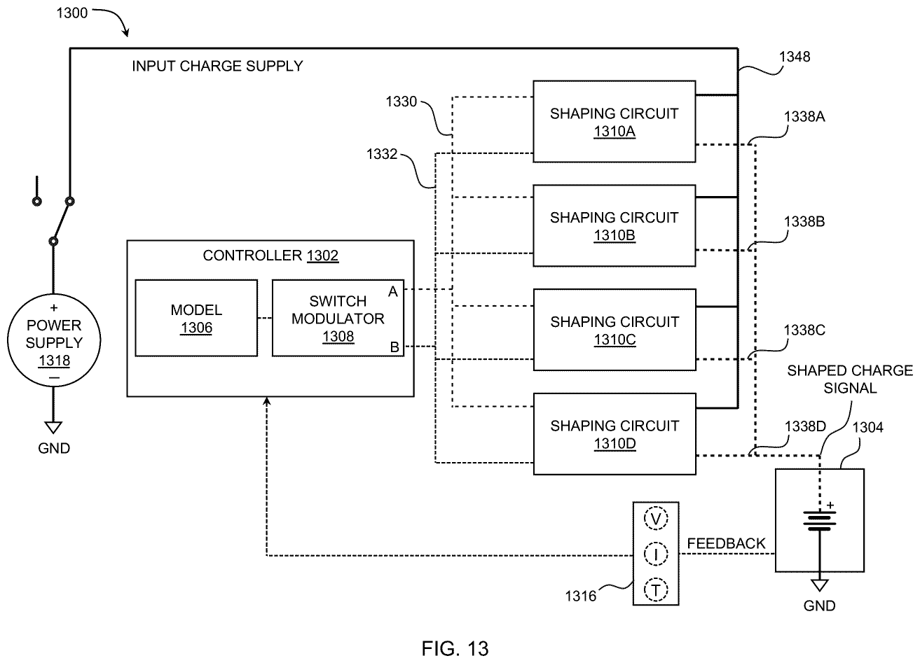

As seen in Equation 3, the determination of average body current depends on body current and body time. Referring to FIG. 12, a shaped charge signal 1200 is illustrated where body current and body time may deviate from the target body current and the target body time, t_{b}. Charge signal 1200 includes a waveform W₃ and a waveform W₂ within a period T. The waveform W₃ may have a high body current I_{b,H} and the waveform W₂ may have a low body current I_{b,L} compared to the target body current. In this example, high body current is further from the target body current than the low body current. If a constant body time is maintained, a period T may include several waveforms before reaching an average body current that is within threshold of the target. In some embodiments, minimizing the number of waveforms within period T and/or minimizing the length of period T may allow an actual waveform to more closely approximate a target waveform. With this in mind, small adjustments to the body time t_{b} can be used to reach an average body current and/or area over fewer waveforms. In this example, body time t_{b,H} of waveform W₃ is reduced compared to the target body time t_{b}, thereby reducing the effect of the higher body current within the average body current calculation of Equation 3. In some embodiments, body time for a given waveform may be adjusted to be longer or shorter than a target body time depending on the target average area selected by the model.

PWM-level and waveform-level dithering has been described with respect to a single phase (e.g., single shaping circuit 110) charging circuit 100; however, these concepts may also be implemented in a multiphase charging circuit. FIG. 13 is a simplified block diagram of a charging path within a multiphase charging circuit 1300. The circuit 1300 includes a power supply 1318 that provides an input charge supply to the system. Specifically, the input charge supply is provided as an input to each of the shaping circuit stages 1310A-1310D and each shaping circuit stage may include the same or similar components as described with respect to shaping circuit 110 of FIG. 1. In alternative embodiments, the shaping circuit stages 1310A-1310D may each include two switching elements while other components such as inductors and/or capacitors may be placed in series ahead of the battery such that a single group of inductors and/or capacitors is included within the circuit 1300 instead of one group per stage. Additionally, while four stages are illustrated and described in the following examples, more or fewer stages may be included within a multiphase charging circuit without departing from the scope of the present disclosure.

Switching elements (e.g., first and second switching elements, not shown) within each stage 1310A-1310D receive instructions from a controller 1302 such that the switching elements are controlled to be on or off at each step increment within a PWM cycle. In this example, “on” refers to a configuration where at least a first inductor is in electrical communication with a power supply 1318 via a first switching element and “off” refers to a configuration where at least the first inductor is electrically grounded via a second switching element. A first switching element within each stage 1310A-1310D may receive a first instruction signal 1330 and a second switching element may receive a second instruction signal 1332, where first and second switching elements are generally controlled to be in opposite on and off states as described with respect to FIG. 2. The on/off instructions for each step increment may be based on information received from a model 1306. The model 1306 receives feedback information about the battery 1304 from a battery monitoring module 1316 and may select a target shaped charge waveform based on conditions at the battery or within the surrounding environment. Each stage generates an output 1338A-1338D that may include at least a portion of a shaped charge signal received by the battery 1304.

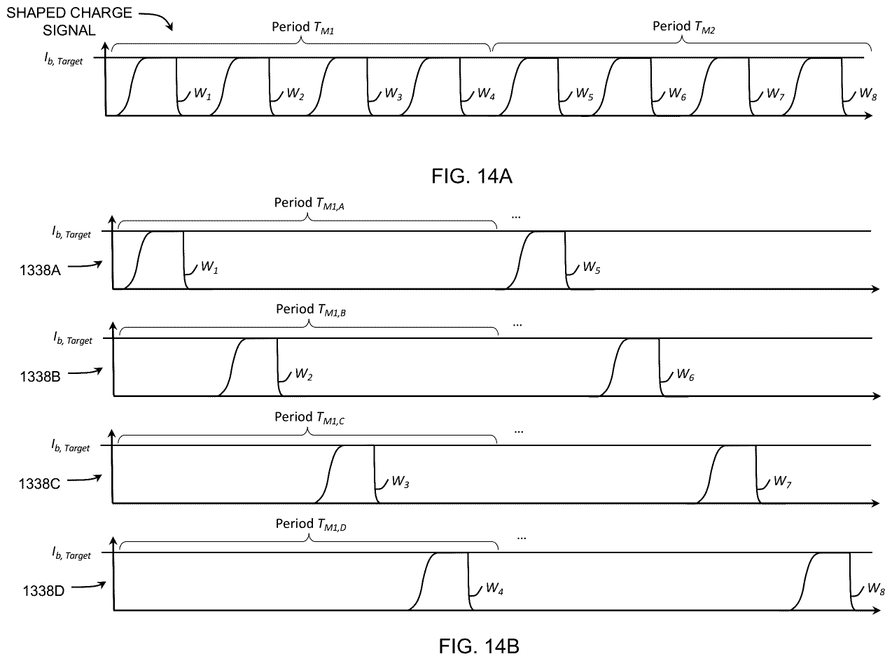

Referring to FIGS. 14A and 14B, examples of a shaped charge signal and stage outputs 1338A-1338D for the multiphase charging circuit 1300 are illustrated. In FIG. 14A, a first multiphase period T_{M1} within the shaped charge signal includes four waveforms W₁-W₄ and a second multiphase period T_{M2} includes four waveforms W₅-W₈. For simplicity, each of the waveforms has the same target body current I_{b,Target}, though more complex shaped charge signals may be generated as will be discussed in further detail below. In this example, a first stage (e.g., first shaping circuit 1310A) has an output 1338A that includes a single waveform W₁ within a multiphase period T_{M1,A}. The waveform W₁ in the output 1338A of first stage 1310A is compiled into a shaped charge signal as waveform W₁. The first stage 1310A may continue to generate this output 1338A over subsequent periods such that additional waveforms (e.g., waveform W₅) are generated and included within the complete shaped charge signal. This example shows shaping circuits 1310A-1310D contributing one waveform for each of the multiphase periods T_{M1}, T_{M2}; however, other ways of alternating, layering, and superimposing waveforms are possible without departing from the scope of the present disclosure.

Second through fourth stages 1310B-1310D operate in a similar way to produce outputs 1338B-1338D, respectively. These outputs may differ from the first output 1338A in terms of timing of the waveform generated for the multiphase periods T_{M1}, T_{M2}. For example, waveform W₁ generated using first stage 1310A and waveform W₂ generated using second stage 1310B are temporally offset from each other such that the positions of the waveforms when compiled into the shaped charge signal match a profile selected by the model. In this way, each of the stage periods T_{M1,A}-T_{M1,D} may differ from each other in terms of timing, but may be the same in terms of duty cycle, average body current, and/or average area calculated over the period. In some embodiments, one or more of the waveforms may be generated using PWM-level dithering to achieve specific leading edge shapes, body current values, rest currents, and/or cold weather mitigation oscillations. As discussed above, the PWM-level dithering may improve resolution of a charging system for a given clock speed and/or may reduce clock speed requirements without sacrificing resolution so that cost and complexity of the system may be reduced. Additionally, while it may be advantageous to distribute waveform generation evenly among the plurality of stages in a multistage system, it is not a requirement. For example, certain stages may be used to produce proportionally more or fewer of the waveforms when compared to other stages.

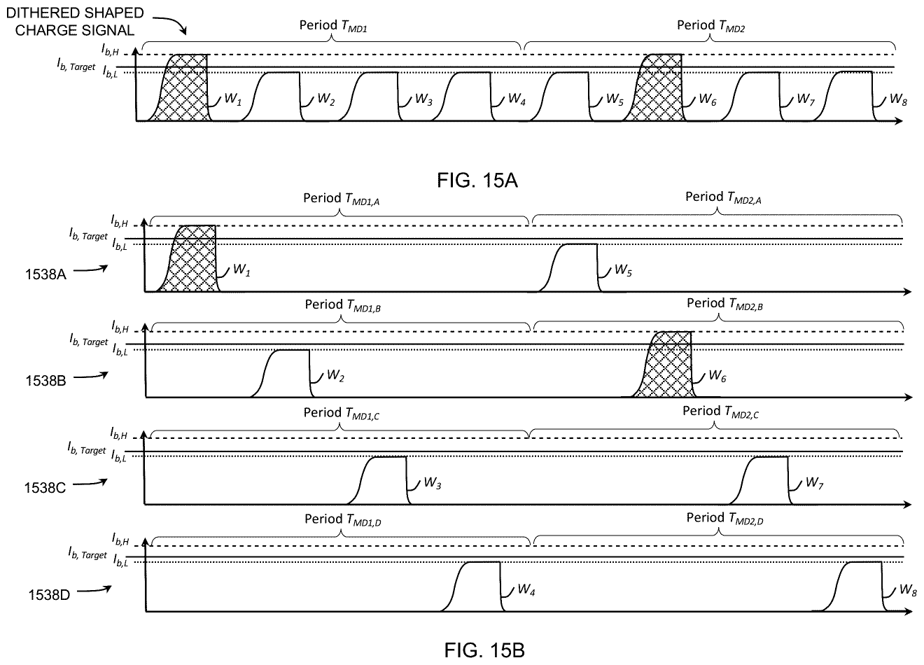

Waveform-level dithering may also be implemented in a multiphase system to further control the current received by the battery. Referring to FIG. 15A, an example of a dithered shaped charge signal is illustrated where at least one waveform has a body portion at a current level that is different from a target body current and/or an area under the curve that is different from a target area under the curve. In some embodiments, the system or circuit used to generate the dithered shaped charge signal may have insufficient resolution, even with the implementation of PWM-level dithering, to achieve the target body current at each waveform. The system may be capable of holding a body current at a relatively higher current (e.g., high current I_{b,H}) or at a relatively lower current (e.g., low current I_{b,L}) compared to the target body current I_{b,Target}. Similar to the single phase embodiment described above with respect to FIGS. 11 and 12, waveforms with a body current at the high current and low current levels may be generated in a selected proportion such that an average body current over a period T_{MD1} is within tolerance of the target body current.

In the example of FIG. 15A, first and second multiphase dithered periods T_{MD1}, T_{MD2} within a dithered shaped charge signal are illustrated. For purposes of demonstrating the concept, this embodiment assumes that one waveform with a body portion at high current and three waveforms with a body portion at low current achieves an average body current equal to a target body current over a four waveform period. Body times associated with each waveform may be constant or may be varied to achieve an average target body current and/or average target area over the periods T_{MD1}, T_{MD2}.

The first period T_{MD1} of the shaped charge signal includes one waveform W₁ that has a body portion at high current I_{b,H} and the remaining waveforms W₂-W₄ have a body portion at a low current I_{b,L}. Waveform W₁ is the first waveform of the period T_{MD1} and is generated by the first shaping circuit 1310A in the first stage output 1538A, as illustrated in FIG. 15B. Second multiphase dithered period T_{MD2} also has one waveform W₆ that has a body portion at high current I_{B,H} and the remaining waveforms W₅, W₇-W₈ have a body portion at a low current I_{b,L}. Notably, waveform W₆ is the second waveform of the period T_{MD2} and is generated by the second shaping circuit 1310B in the second stage output 1538B. While not specifically shown, a third period within the shaped charge signal may be configured such that the third shaping circuit 1310C generates the high current waveform, and so on such that each shaping circuit is used evenly in rotation.

The two dithered periods T_{MD1} and T_{MD2} are not identical but do have equal average body currents and average areas. The two periods differ in that generation of the high current waveform is divided between different shaping circuits. By alternating which shaping circuit creates higher and lower waveforms and by preventing a single shaping circuit from generating all, a majority, and/or sequential instances of the higher current waveforms, temperature buildup within the system may be reduced and wear across the shaping circuits may be evenly distributed. These improvements may advantageously lead to higher durability and longer life of the system. Additionally, from the battery perspective, it may be advantageous to implement such a methodology because the high current waveforms occur in a regular pattern over at least a portion of the shaped charge signal. This may improve charging efficiency and reduce signal noise compared with methods where high current waveforms are delivered irregularly.

While not specifically illustrated in the FIGS. 15A and 15B, multiphase systems may also be dithered by adjusting body time as discussed with respect to FIG. 12 above. Body current and body time affect average body current over a period and average area and thus may be used as variables to achieve target metrics. In some applications, large deviations between body current times of different waveforms may introduce noise into the shaped charge signal. As such, the adjustment of body current and proportion of different waveforms generated within a period may be performed first, followed by small changes to the body time of different waveforms to fine tune the average body current and average areas of the period.

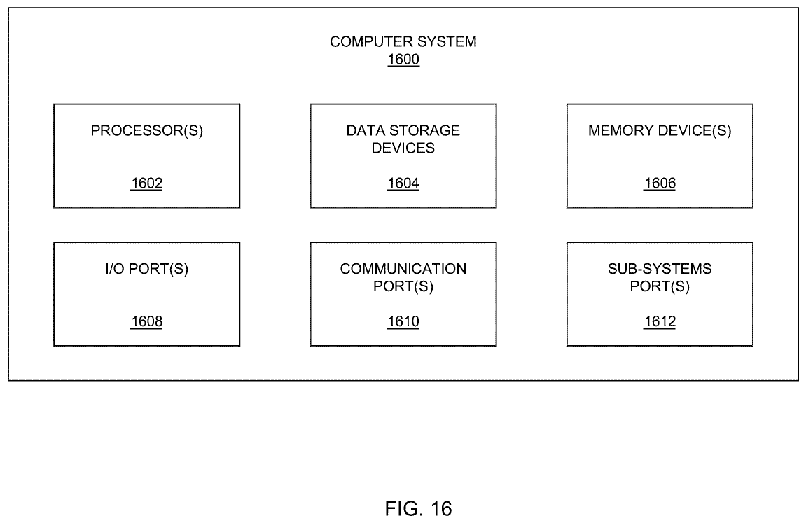

Referring to FIG. 16, a detailed description of an example computing system 1600 having one or more computing units that may implement various systems and methods discussed herein is provided. The computing system 1600 may be part of a controller, may be in operable communication with various implementation discussed herein, may run various operations related to the method discussed herein, may run offline to process various data for characterizing a battery, and may be part of overall systems discussed herein. The computing system 1600 may process various signals discussed herein and/or may provide various signals discussed herein. For example, battery measurement information may be provided to such a computing system 1600. The computing system 1600 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 1600 may be a computing system that may execute a computer program product to execute a computer process. Data and program files may be input to the computer system 1600, which reads the files and executes the programs therein. Some of the elements of the computer system 1600 are shown in FIG. 16, including one or more hardware processors 1602, one or more data storage devices 1604, one or more memory devices 1606, and/or one or more ports 1608-1612. Additionally, other elements that will be recognized by those skilled in the art may be included in the computing system 1600 but are not explicitly depicted in FIG. 16 or discussed further herein. Various elements of the computer system 1600 may communicate with one another by way of one or more communication buses, point-to-point communication paths, or other communication means not explicitly depicted in FIG. 16. Similarly, in various implementations, various elements disclosed in the system may or not be included in any given implementation.

The processor 1602 may include, for example, a central processing unit (CPU), a microprocessor, a microcontroller, a digital signal processor (DSP), and/or one or more internal levels of cache. There may be one or more processors 1602, such that the processor 1602 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 1604, stored on the memory device(s) 1606, and/or communicated via one or more of the ports 1608-1612, thereby transforming the computer system 1600 in FIG. 16 to a special purpose machine for implementing the operations described herein.

The one or more data storage devices 1604 may include any non-volatile data storage device capable of storing data generated or employed within the computing system 1600, such as computer executable instructions for performing a computer process, which may include instructions of both application programs and an operating system (OS) that manages the various components of the computing system 1600. The data storage devices 1604 may include, without limitation, magnetic disk drives, optical disk drives, solid state drives (SSDs), flash drives, and the like. The data storage devices 1604 may include removable data storage media, non-removable data storage media, and/or external storage devices made available via a wired or wireless network architecture with such computer program products, including one or more database management products, web server products, application server products, and/or other additional software components. Examples of non-removable data storage media include internal magnetic hard disks, SSDs, and the like. The one or more memory devices 1606 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 1604 and/or the memory devices 1606, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 1600 includes one or more ports, such as an input/output (I/O) port 1608, a communication port 1610, and a sub-systems port 1612, for communicating with other computing, network, or vehicle devices. It will be appreciated that the ports 1608-1612 may be combined or separate and that more or fewer ports may be included in the computer system 1600. The I/O port 1608 may be connected to an I/O device, or other device, by which information is input to or output from the computing system 1600. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 1600 via the I/O port 1608. In some examples, such inputs may be distinct from the various system and method discussed with regard to the preceding figures. Similarly, the output devices may convert electrical signals received from computing system 1600 via the I/O port 1608 into signals that may be sensed or used by the various methods and system discussed herein. The input device may be an alphanumeric input device, including alphanumeric and other keys for communicating information and/or command selections to the processor 1602 via the I/O port 1608.

The environment transducer devices convert one form of energy or signal into another for input into or output from the computing system 1600 via the I/O port 1608. For example, an electrical signal generated within the computing system 1600 may be converted to another type of signal, and/or vice-versa. In one implementation, the environment transducer devices sense characteristics or aspects of an environment local to or remote from the computing device 1600, such as battery voltage, open circuit battery voltage, charge current, battery temperature, light, sound, temperature, pressure, magnetic field, electric field, chemical properties, and/or the like.

In one implementation, a communication port 1610 may be connected to a network by way of which the computer system 1600 may receive network data useful in executing the methods and systems set out herein as well as transmitting information and network configuration changes determined thereby. For example, charging protocols may be updated, battery measurement or calculation data shared with external system, and the like. The communication port 1610 connects the computer system 1600 to one or more communication interface devices configured to transmit and/or receive information between the computing system 1600 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 1610 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 1600 may include a sub-systems port 1612 for communicating with one or more systems related to a device being charged according to the methods and system described herein to control an operation of the same and/or exchange information between the computer system 1600 and one or more sub-systems of the device. Examples of such sub-systems of a vehicle, include, without limitation, motor controllers and systems, battery control systems, and others.

The system set forth in FIG. 16 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A charging circuit comprising:
at least one switching element receiving an input charge supply from a power supply; and
a controller comprising a switch modulator providing a pulse-width modulated (PWM) control signal to the at least one switching element to shape the input charge signal as an output charge signal, the PWM control signal comprising a plurality of cycles per a sample period;
wherein the PWM control signal comprises a first duty cycle during a first cycle of the sample period and a second duty cycle within a second cycle of the sample period, and wherein the first duty cycle and the second duty cycle are different.

2. The charging circuit of claim 1, wherein the PWM signal comprises the first duty cycle during one cycle and the second duty cycle within a remaining plurality of cycles within the sample period.

3. The charging circuit of claim 2, wherein the first duty cycle is higher than the second duty cycle.

4. The charging circuit of claim 1, further comprising a battery electrically coupled with the at least one switching element and configured to receive the shaped output charge signal.

5. The charging circuit of claim 4, further comprising a battery measurement module electrically coupled with the battery and the controller, wherein the battery measurement module is configured to measure battery characteristics at the battery and provide feedback to the controller.

6. The charging circuit of claim 5, wherein the feedback comprises at least one of measured battery characteristics and calculated battery characteristics.

7. The charging circuit of claim 5, wherein the controller further comprises a model, wherein the model is configured to receive the feedback from the battery measurement module, the model is configured to update based on the feedback from the battery measurement module, the model configured to generate instructions for controlling the PWM signal to shape the input charge signal.

8. The charging circuit of claim 7, wherein the instructions comprise duty cycle selections for a plurality of duty cycles within the sample period.

9. The charging circuit of claim 1, wherein the at least one switching element comprises a first switching element and a second switching element, a source of the second switching element coupled with a drain of the first switching element at a node, the shaping circuit further comprises an inductor electrically coupled with the node.

10. The charging circuit of claim 1, wherein the shaped charge signal comprises a plurality of charge waveforms, each charge waveform comprising a shaped leading edge and a body portion, wherein the body portion of the charge waveform comprises a body current sustained over a body time.

11. The charging circuit of claim 10, wherein the plurality of charge waveforms comprises:
a first charge waveform having a first body current; and
a second charge waveform having a second body current,
wherein the first and second body currents are different.

12. The charging circuit of claim 10, wherein the plurality of waveforms comprises:
at least one waveform having a first body time; and
at least one waveform having a second body time,
wherein the first and second body times are different.

13. The charging circuit of claim 10, wherein the first charge waveform and the second charge waveform are at least part of a repeating sequence of charge waveforms within the shaped charge signal.

14. The charging circuit of claim 13, wherein an average body charge over the repeating sequence of charge waveforms within the shaped charge signal is within a predetermined tolerance of a target body charge.

15. The charging circuit of claim 10, further comprising a first shaping circuit and a second shaping circuit, wherein the first shaping circuit is configured to generate the first charge waveform having the first body current and wherein the second shaping circuit is configured to generate the second charge waveform having the second body current.

16. The charging circuit of claim 10, further comprising a first shaping circuit and a second shaping circuit, wherein the first shaping circuit is configured to generate the first charge waveform having the first body time and wherein the second shaping circuit is configured to generate the second charge waveform having the second body time.

17. A method of generating a shaped charge signal comprising:
providing a charging circuit comprising a switch modulator in electrical communication with at least a first switching element within a shaping circuit;
providing an input charge supply to the first the switching element;
generating, at the switch modulator, a first instruction signal for controlling the first switching element, wherein the first instruction signal comprises a first sample period, wherein the first sample period is divided into a plurality of PWM cycles, each PWM cycle having a PWM duty cycle;
operably controlling the first switching element via the first instruction signal such that, within the first sample period, a first of the plurality of PWM cycles has a first duty cycle and a second of the plurality of PWM cycles has a second duty cycle different from the first duty cycle.

18. A method of generating a shaped charge signal comprising:
providing a charging circuit comprising a switch modulator in electrical communication with a first switching element within a shaping circuit;
providing an input charge supply to the first the switching element;
generating, at the switch modulator, a first instruction signal for controlling the first switching element;
operably controlling the first switching element to generate a first shaped waveform having a first body current and a first body time;
operably controlling the first switching element to generate a second shaped waveform having a second body current and a second body time.

19. The method of claim 18, wherein the first body current is different from the second body current.

20. The method of claim 19, wherein a repeating period of the shaped charge signal comprises at least one first waveform and at least one second waveform.

21. The method of claim 19, wherein the first body time is different from the second body time.

22. A method of generating a shaped charge signal comprising:
providing a charging circuit comprising a switch modulator, the switch modulator in electrical communication with a first switching element of a first shaping circuit and in electrical communication with a second switching element of a second shaping circuit;
providing an input charge supply to the first the switching element and the second switching element;
generating, at the switch modulator, a first instruction signal for controlling the first switching element and a second instruction signal for controlling the second switching element;
operably controlling the first switching element to generate a first shaped waveform having a first body current and a first body time; and
operably controlling the second switching element to generate a second shaped waveform having a second body current and a second body time.

23. The method of claim 22, wherein the first body current is different from the second body current, and wherein the first body time is different from the second body time.
